(19) United States
(12) Patent Application Publication
(10) Pub. No.: US 2021/0359157 A1
(43) Pub. Date: Nov. 18, 2021

(54) DISPLAY DEVICE AND METHOD FOR FABRICATING SAME

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Zhiping HU, Shenzhen, Guangdong (CN)

(21) Appl. No.: 16/622,962

(22) PCT Filed: Dec. 6, 2019
(86) PCT No.: PCT/CN2019/123471

§ 371 Date: Dec. 16, 2019

(30) Foreign Application Priority Data
Nov. 22, 2019 (CN) 201911152338.8

(51) Int. Cl. H01L 33/10; H01L 33/50; H01L 27/15; H01L 33/00

(52) U.S. Cl. CPC H01L 33/10; H01L 33/502; H01L 2933/0016; H01L 33/005; H01L 27/156

(57) ABSTRACT

The present disclosure provides a display device and a method for fabricating the same. The display device comprises an array substrate and a plurality of micro light emitting diode devices arranged in an array on the array substrate. Each micro light emitting diode device comprises a first substrate, a second substrate disposed on the first substrate, and a micro light emitting diode. Light extraction efficiency of the micro light emitting diode is improved by providing a reflective hole on the second substrate and disposing the micro light emitting diode in the reflective hole.

### FIELD OF INVENTION

The present disclosure relates to a field of display technology, and particularly to a display device and a method for fabricating the same.

### BACKGROUND

Currently, inorganic semiconductor-based light emitting diodes (LEDs) are widely used in solid-state light sources or backlights of liquid crystal display devices because of their high luminous efficiency, low cost, long service life, and environmental friendliness. In a liquid crystal display device, most of light emitted by LEDs is absorbed by a color filter after being deflected by liquid crystals, and only a small portion of the light is emitted out of the liquid crystal display device, resulting in a light utilization rate of only 2.8%. This means that a brightness of a backlight needs to be greater than ten times a brightness required for the liquid crystal display device.

In order to improve light utilization rate and reduce power consumption cost, a variety of new active display technologies have emerged, such as organic light emitting diodes (OLEDs) and micro light emitting diodes (Micro LEDs). Compared with OLEDs, Micro LEDs have an advantage of material stability and are more prominent in terms of brightness and service life. For Micro LEDs, there are two options for achieving full color display. One option is to transfer a large number of red, green, and blue Micro LEDs to corresponding positions. The other option is to transfer only blue Micro LEDs and further adopt quantum dots for red and green pixels. The blue Micro LEDs excite quantum dots. In a process of energy transfer, there will inevitably be a large amount of energy loss, such as loss caused by waveguide effect of Micro LEDs, and scattering effect and self-absorption of quantum dots. Therefore, in a photoluminescence process, light loss is excessive, resulting in a low light utilization rate.

In the above, current Micro LED display devices have a problem that excessive light loss during a photoluminescence process results in a low light utilization rate. Therefore, it is necessary to provide a display device and a method for fabricating the same to improve this defect.

### SUMMARY OF DISCLOSURE

The present disclosure provides a display device and a method for fabricating the same to solve the problem that, in current Micro LED display, excessive light loss during a photoluminescence process results in a low light utilization rate.

The present disclosure provides a display device, comprising:

an array substrate; and

a plurality of micro light emitting diode devices arranged in an array on the array substrate;

wherein each micro light emitting diode device comprises a first substrate, a second substrate disposed on the first substrate and provided with a reflective hole penetrating the second substrate, and a micro light emitting diode located in the reflective hole.

In an embodiment, a cross section of the reflective hole is shaped as an inverted trapezoid, and a sidewall of the reflective hole forms an oblique angle with a bottom surface of the second substrate.

In an embodiment, the oblique angle is between 15° and 60°.

In an embodiment, a height of the second substrate in a direction perpendicular to the array substrate is greater than that of the micro light emitting diodes.

In an embodiment, the micro light emitting diodes comprises blue micro light emitting diodes, red micro light emitting diodes, and green micro light emitting diodes.

In an embodiment, the display device further comprises a plurality of quantum dot layers disposed in some of the reflective holes and covering some of the micro light emitting diodes. The micro light emitting diodes are blue micro light emitting diodes.

In an embodiment, the quantum dot layers are composed of a photocurable material comprising quantum dots.

In an embodiment, the second substrate is composed of gold, silver, or aluminum.

The present disclosure further provides a display device comprising:

an array substrate; and

a plurality of micro light emitting diode devices arranged in an array on the array substrate;

wherein each micro light emitting diode device comprises a first substrate, a second substrate disposed on the first substrate and provided with a reflective hole penetrating the second substrate, and a blue micro light emitting diode located in the reflective hole; and

wherein some of the reflective holes are provided with quantum dot layers covering the blue micro light emitting diodes in which.

In an embodiment, a cross section of the reflective hole is shaped as an inverted trapezoid, and a sidewall of the reflective hole forms an oblique angle with a bottom surface of the second substrate.

In an embodiment, the oblique angle is between 15° and 60°.

In an embodiment, a height of the second substrate in a direction perpendicular to the array substrate is greater than that of the micro light emitting diodes.

In an embodiment, the quantum dot layers comprise red quantum dot layers and green quantum dot layers.

In an embodiment, the quantum dot layers are composed of a photocurable material comprising quantum dots.

In an embodiment, the second substrate is composed of gold, silver, or aluminum.

The present disclosure further provides a method for fabricating a display device, comprising:

providing a second substrate having a plurality of holes arranged in an array;

sanding and polishing the holes to form a plurality of reflective holes;

providing a first substrate having a plurality of metal electrodes;

transferring a plurality of micro light emitting diodes to the first substrate;

bonding the second substrate to the first substrate to form a light emitting diode substrate, wherein the micro light emitting diodes are located in the reflective holes one by one; and

cutting the light emitting diode substrate to form a plurality of single micro light emitting diode devices.

In an embodiment, the method further comprises:

transferring the micro light emitting diode devices to an array substrate; and

filling quantum dot solutions in some of the reflective holes and curing them to form quantum dot layers covering the micro light emitting diodes.

The present disclosure provides a display device comprising an array substrate and micro light emitting diode devices. Each micro light emitting diode device comprises a first substrate, a second substrate, and a micro light emitting diode. The second substrate is provided with a reflective hole. The micro light emitting diode is located in the reflective hole. A smooth sidewall of the reflective hole reflects and extracts light to improve light extraction efficiency of the micro light emitting diode.

### BRIEF DESCRIPTION OF DRAWINGS

In order to more clearly illustrate the technical solutions in the embodiments of the present disclosure, a brief description of accompanying drawings used in the description of the embodiments of the present disclosure will be given below. Obviously, the accompanying drawings in the following description are merely some embodiments of the present disclosure. For those skilled in the art, other drawings may be obtained from these accompanying drawings without creative labor.

FIG. 1 is a cross-sectional side view of a display device according to a first embodiment of the present disclosure.

FIG. 2 is a cross-sectional side view of a micro light emitting diode device according to the first embodiment of the present disclosure.

FIG. 3 is a cross-sectional side view of a display device according to a second embodiment of the present disclosure.

FIG. 4A is a structural schematic diagram of a second substrate according to a third embodiment of the present disclosure.

FIG. 4B is a structural schematic diagram of a first substrate according to the third embodiment of the present disclosure.

FIG. 4C is a structural schematic diagram of the first substrate according to the third embodiment of the present disclosure.

FIG. 4D is a structural schematic diagram of a light emitting diode substrate according to the third embodiment of the present disclosure.

FIG. 4E is a structural schematic diagram of micro light emitting diode devices according to the third embodiment of the present disclosure.

FIG. 4F is a structural schematic diagram of an array substrate according to the third embodiment of the present disclosure.

FIG. 4G is a structural schematic diagram of the array substrate according to the third embodiment of the present disclosure.

### DETAILED DESCRIPTION

The following description of various embodiments of the present disclosure with reference to the accompanying drawings is used to illustrate specific embodiments that can be practiced. Directional terms mentioned in the present disclosure, such as “above”, “below”, “front”, “rear”, “left”, “right”, “inside”, “outside”, “side”, are merely used to indicate the direction of the accompanying drawings. Therefore, the directional terms are used for illustrating and understanding the present disclosure rather than limiting the present disclosure. In the figures, elements with similar structure are indicated by the same reference numerals.

The present invention will be further described below in conjunction with accompanying drawings and specific embodiments.

### First Embodiment

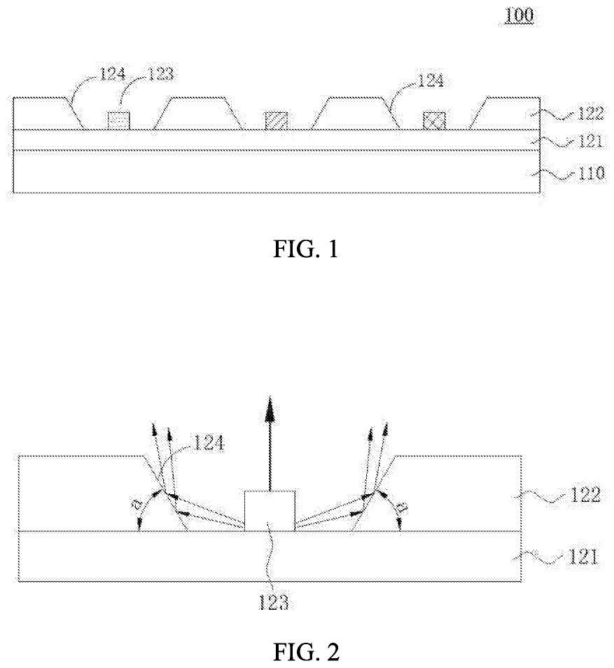

The present disclosure provides a display device, which will be described in detail below in conjunction with FIG. 1 and FIG. 2.

Please refer to FIG. 1, which is a cross-sectional side view of a display device 100 according to a first embodiment of the present disclosure. The display device 100 comprises an array substrate 110 and a plurality of micro light emitting diode devices arranged in an array on the array substrate 110. The array substrate 110 is provided with thin film transistors and pixel driving circuits.

Please refer to FIG. 2, which is a cross-sectional side view of a micro light emitting diode device according to the first embodiment of the present disclosure. The micro light emitting diode device comprises a first substrate 121, a second substrate 122 disposed on the first substrate 121, and a micro light emitting diode 123. The first substrate 121 is provided with a metal electrode. The micro light emitting diode 123 is connected to the metal electrode. The second substrate 122 is provided with a reflective hole 124 penetrating itself. The micro light emitting diode 123 is located in the reflective hole 124. A sidewall of the reflective hole 124 is smooth to reflect and extract light emitted by the micro light emitting diode 123. The sidewall of the reflective hole 124 reflects light diverged from sides of the micro light emitting diode 123 as indicated by arrows to a light emitting direction of the micro light emitting diode 123, thereby concentrating the light emitted by the micro light emitting diode 123. Therefore, light extraction efficiency of the micro light-emitting diode 123 is improved.

In this embodiment, a cross section of the reflective hole 124 is shaped as an inverted trapezoid, and a sidewall of the reflective hole 124 forms an oblique angle with a bottom surface of the second substrate 122. The sidewall having the oblique angle a can reflect the light diverged from the micro light-emitting diode 123 to the light emitting direction, thereby improving the light extraction efficiency of the micro light emitting diode 123.

Preferably, the oblique angle a is between 15° and 60° in order to ensure reflection effect without affecting a light viewing angle.

Preferably, the first substrate 121 may be composed of a ceramic material. The metal electrode may be composed of a highly conductive metal material such as silver, aluminum, and copper.

In this embodiment, the micro light emitting diodes 123 comprises blue micro light emitting diodes, red micro light emitting diodes, and green micro light emitting diodes, thereby achieving full color display of the display device 100. The micro light-emitting diodes of the respective colors may be arranged according to an arrangement of sub-pixel regions of the display device, which is not limited herein.

In this embodiment, a height of the second substrate 122 in a direction perpendicular to the array substrate 110 is greater than that of the micro light emitting diodes 123 to limit the micro light emitting diodes 123 within the reflective holes 124, thereby improving reflection and extraction effects of the reflective holes 124 on the light emitted by the micro light emitting diodes 123. Furthermore, the second substrate 122 can also serve as a dam between adjacent micro light emitting diodes 123, which can reduce crosstalk of light emitted by adjacent different color micro light emitting diodes, thereby improving display effect of the display device 100.

Preferably, in order to ensure the reflection effect of the reflective holes 124 and light blocking effect of the second substrate 122 as a dam, the second substrate 122 may be composed of a metal material having a high reflectance such as gold, silver, and aluminum. In some embodiments, the second substrate 122 may also be composed of other non-transparent non-metallic materials having higher reflectance, which are not limited herein.

The present disclosure provides a display device 100 comprising an array substrate 110 and micro light emitting diode devices. Each micro light emitting diode device comprises a first substrate 121, a second substrate 122, and a micro light emitting diode 123. The second substrate 122 is provided with a reflective hole 124. The micro light emitting diode 123 is located in the reflective hole 124. A smooth sidewall of the reflective hole 124 reflects and extracts light to improve light extraction efficiency of the micro light emitting diode 123.

### Second Embodiment

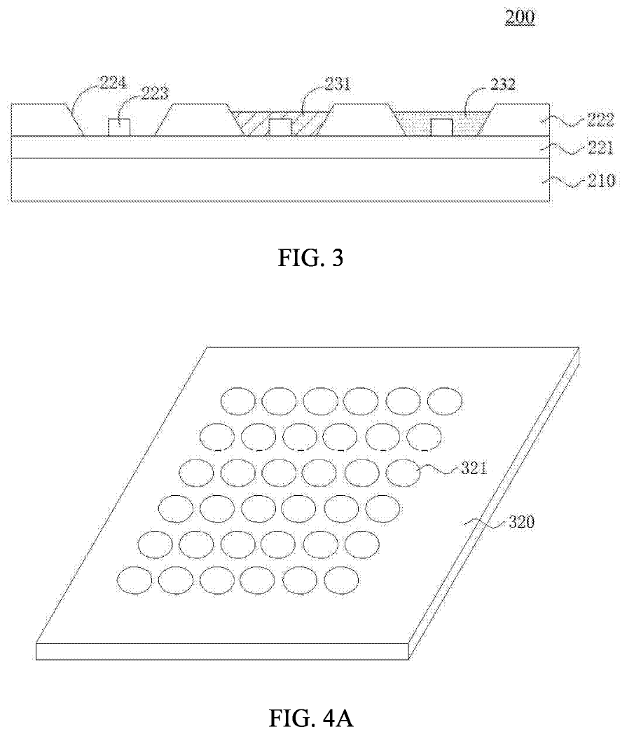

The present disclosure further provides a display device, which will be described in detail below in conjunction with FIG. 3.

Please refer to FIG. 3, which is a cross-sectional side view of a display device 200 according to a second embodiment of the present disclosure. The display device 200 comprises an array substrate 210 and a plurality of micro light emitting diode devices arranged in an array on the array substrate 210.

The micro light emitting diode device comprises a first substrate 221, a second substrate 222 disposed on the first substrate 221, and a micro light emitting diode 223. The first substrate 221 is provided with a metal electrode. The micro light emitting diode 223 is connected to the metal electrode. The second substrate 222 is provided with a reflective hole 224 penetrating itself. The micro light emitting diode 223 is located in the reflective hole 224. A sidewall of the reflective hole 224 is smooth to reflect and extract light emitted by the micro light emitting diode 223. The sidewall of the reflective hole 224 reflects light diverged from sides of the micro light emitting diode 223 as indicated by arrows to a light emitting direction of the micro light emitting diode 223, thereby concentrating the light emitted by the micro light emitting diode 223. Therefore, light extraction efficiency of the micro light-emitting diode 223 is improved.

In this embodiment, a cross section of the reflective hole 224 is shaped as an inverted trapezoid, and a sidewall of the reflective hole 224 forms an oblique angle with a bottom surface of the second substrate 222. The sidewall having the oblique angle a can reflect the light diverged from the micro light-emitting diode 223 to the light emitting direction, thereby improving the light extraction efficiency of the micro light emitting diode 223.

Preferably, the oblique angle a is between 15° and 60° in order to ensure reflection effect without affecting a light viewing angle.

In this embodiment, the display device 200 further comprises a plurality of quantum dot layers disposed in some of the reflective holes 224 and covering some of the micro light emitting diodes 223 in the some of the reflective holes 224. The micro light emitting diodes 223 are blue micro light emitting diodes. The quantum dot layers comprise red quantum dot layers 231 and green quantum dot layers 232. The red quantum dot layer 231 and the micro light emitting diode located below thereof correspond to a red sub-pixel region of the array substrate 210. The green quantum dot layer 232 and the micro light emitting diode located below thereof correspond to a green sub-pixel region of the array substrate 210. The blue micro light emitting diode not covered by the quantum dot layer corresponds to blue sub-pixel regions. The corresponding quantum dot layers convert the light emitted by the blue micro light emitting diodes to achieve full color display of the display device 200.

Preferably, the quantum dot layers are composed of a photocurable material comprising quantum dots.

In this embodiment, a height of the second substrate 222 in a direction perpendicular to the array substrate 210 is greater than that of the micro light emitting diodes 223 and quantum dot layers to limit the micro light emitting diodes 223 and quantum dot layers within the reflective holes 224. The sidewall having the oblique angle reflects light emitted by the quantum dots in the quantum dot layer to improve reflection and extraction effects of the reflective holes 224 on the light emitted by the micro light emitting diodes 223. Furthermore, the second substrate 222 can also serve as a dam between adjacent micro light emitting diodes 223 and adjacent quantum dot layers, which can reduce crosstalk of light emitted by adjacent micro light emitting diodes 223 and adjacent different color quantum dot layer, thereby improving display effect of the display device 200.

Preferably, in order to ensure the reflection effect of the reflective holes 224 and light blocking effect of the second substrate 222 as a dam, the second substrate 222 may be composed of a metal material having a high reflectance such as gold, silver, and aluminum. In some embodiments, the second substrate 222 may also be composed of other non-transparent non-metallic materials having higher reflectance, which are not limited herein.

The present disclosure provides a display device 200 comprising an array substrate 210 and micro light emitting diode devices. Each micro light emitting diode device comprises a first substrate 221, a second substrate 222, and a micro light emitting diode 223. The second substrate 222 is provided with a reflective hole 224. The micro light emitting diode 223 is located in the reflective hole 224. A smooth sidewall of the reflective hole 224 reflects and extracts light to improve light extraction efficiency of the micro light emitting diode 223.

### Third Embodiment

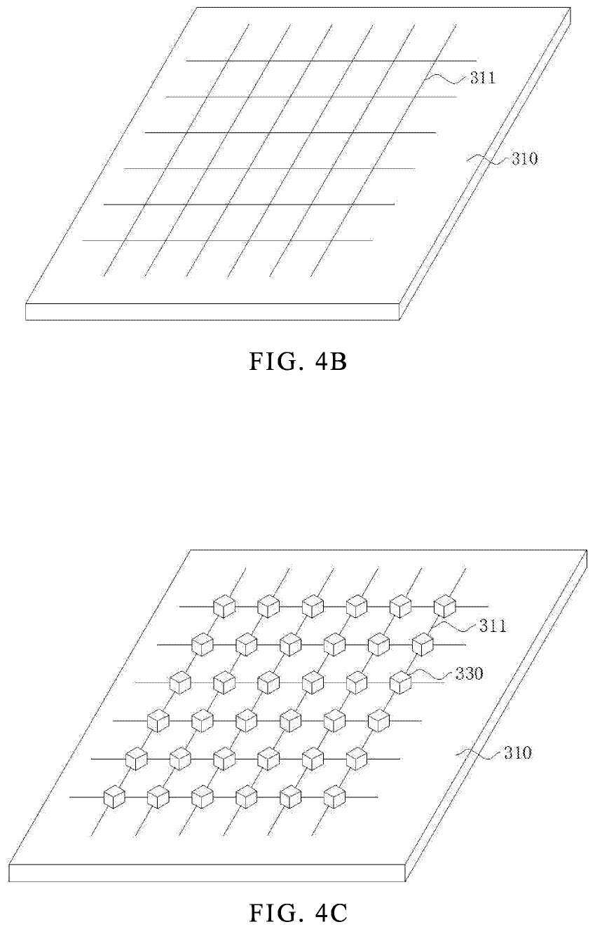

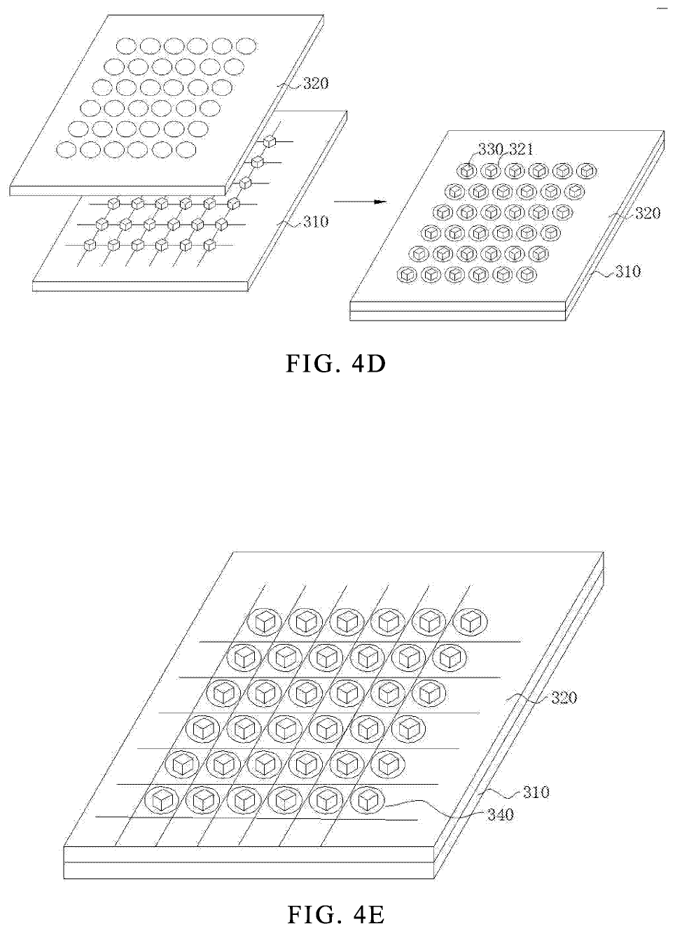

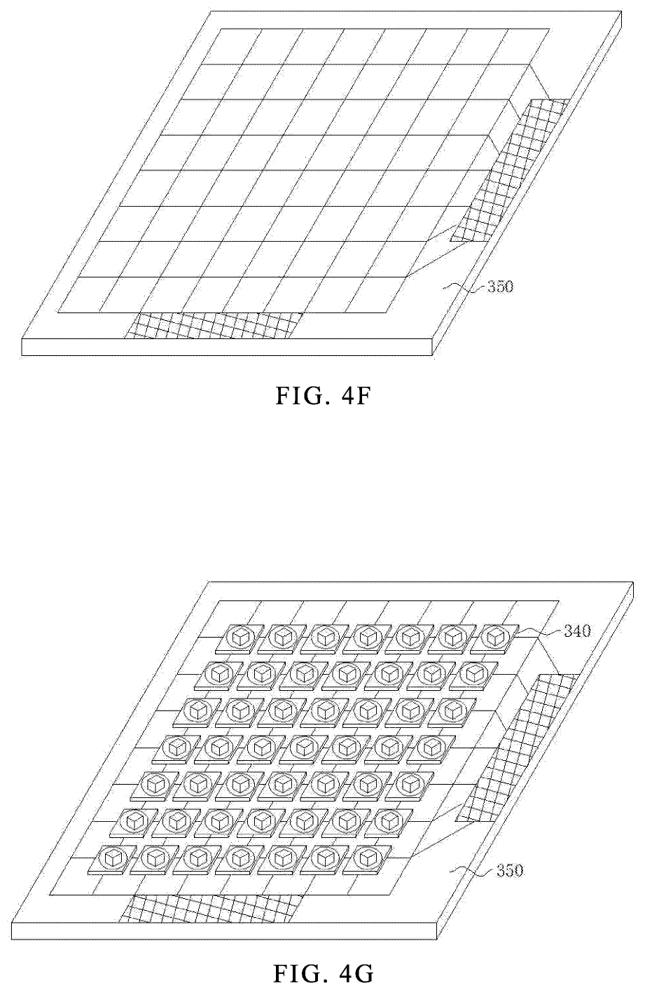

The present disclosure further provides a method for fabricating a display device, which will be described in detail below in conjunction with FIG. 4A to FIG. 4G. FIG. 4A is a structural schematic diagram of a second substrate. FIG. 4B and FIG. 4C are structural schematic diagrams of a first substrate. FIG. 4D is a structural schematic diagram of a light emitting diode substrate. FIG. 4E is a structural schematic diagram of micro light emitting diode devices. FIG. 4F and FIG. 4G are structural schematic diagrams of an array substrate.

The method for fabricating a display device comprises the following steps.

Step S10: as shown in FIG. 4A, providing a second substrate 320 having a plurality of holes arranged in an array.

Step S20: sanding and polishing the holes to form a plurality of reflective holes 321 having smooth sidewalls and a certain oblique angle.

Step S30: as shown in FIG. 4B, providing a first substrate 310 having a plurality of metal electrodes 311.

Step S30: as shown in FIG. 4C, transferring a plurality of micro light emitting diodes 330 to the first substrate 310 and soldering the micro light emitting diodes 330 to the metal electrodes 311.

Step S40: as shown in FIG. 4D, bonding the first substrate 310 and the second substrate 320 with a curing adhesive to form a light emitting diode substrate. The light emitting diodes 330 are located in the reflective holes one by one.

Step S50: as shown in FIG. 4E, cutting the light emitting diode substrate to form a plurality of single micro light emitting diode devices 340.

In this embodiment, in step S10, the reflective holes 321 are formed by mechanical stamping, hot pressing, or air pressing.

The sidewalls of the reflective holes 322 are smooth to reflect and extract light emitted by the micro light emitting diode 330. The sidewall of the reflective hole 322 reflects light diverged from sides of the micro light emitting diode 330 to a light emitting direction of the micro light emitting diode 330, thereby concentrating the light emitted by the micro light emitting diode 330. Therefore, light extraction efficiency of the micro light-emitting diode 330 is improved.

Preferably, the oblique angle a is between 15° and 60° in order to ensure reflection effect without affecting a light viewing angle. The second substrate 320 may be composed of a metal material having a high reflectance such as gold, silver, and aluminum to improve the reflection effect of the reflective holes 322.

The method for fabricating the display device further comprises the following steps.

Step S60: as shown in FIG. 4F, transferring the micro light emitting diode devices 340 to an array substrate 350. The array substrate 350 is provided with pixel driving circuits.

Step S70: as shown in FIG. 4G, filling quantum dot solutions in some of the reflective holes 322 by inkjet printing and curing them to form quantum dot layers covering the micro light emitting diodes 330.

In this embodiment, the micro light emitting diodes 330 are blue micro light emitting diodes. The micro light emitting diodes in different color sub-pixel regions are covered by quantum dot layers having the same color as the sub-pixel regions. The quantum dot layers are configured as light conversion layers to achieve full color display of the display device. In some embodiments, the micro light emitting diode 330 may comprise blue micro light emitting diodes, red micro light emitting diodes, and green micro light emitting diodes. The full color display of the display device is realized by a combination of three-color micro light emitting diodes, and the quantum dot layers described in this embodiment are not required.

The present disclosure provides a method for fabricating a display device. A second substrate 320 is provided with a plurality of reflective holes 322 having smooth sidewalls and arranged in an array. The micro light emitting diodes 330 are disposed in the reflective holes 322. The smooth sidewalls of the reflective holes 322 reflect and extract light to improve light extraction efficiency of the micro light emitting diodes 330.

In the above, the present application has been described in the above preferred embodiments, but the preferred embodiments are not intended to limit the scope of the present application, and those skilled in the art may make various modifications without departing from the scope of the present application. The scope of the present application is determined by claims.

What is claimed is:

1. A display device, comprising:
an array substrate; and
a plurality of micro light emitting diode devices arranged in an array on the array substrate;
wherein each micro light emitting diode device comprises a first substrate, a second substrate disposed on the first substrate and provided with a reflective hole penetrating the second substrate, and a micro light emitting diode located in the reflective hole.

2. The display device according to claim 1, wherein a cross section of the reflective hole is shaped as an inverted trapezoid, and a sidewall of the reflective hole forms an oblique angle with a bottom surface of the second substrate.

3. The display device according to claim 2, wherein the oblique angle is between 15° and 60°.

4. The display device according to claim 1, wherein a height of the second substrate in a direction perpendicular to the array substrate is greater than that of the micro light emitting diodes.

5. The display device according to claim 1, wherein the micro light emitting diodes comprise blue micro light emitting diodes, red micro light emitting diodes, and green micro light emitting diodes.

6. The display device according to claim 1, further comprising a plurality of quantum dot layers disposed in some of the reflective holes and covering some of the micro light emitting diodes, and the micro light emitting diodes are blue micro light emitting diodes.

7. The display device according to claim 6, wherein the quantum dot layers are composed of a photocurable material comprising quantum dots.

8. The display device according to claim 1, wherein the second substrate is composed of gold, silver, or aluminum.

9. A display device, comprising:
an array substrate; and
a plurality of micro light emitting diode devices arranged in an array on the array substrate;
wherein each micro light emitting diode device comprises a first substrate, a second substrate disposed on the first substrate and provided with a reflective hole penetrating the second substrate, and a blue micro light emitting diode located in the reflective hole; and
wherein some of the reflective holes are provided with quantum dot layers covering the blue micro light emitting diodes in which.

10. The display device according to claim 9, wherein a cross section of the reflective hole is shaped as an inverted trapezoid, and a sidewall of the reflective hole forms an oblique angle with a bottom surface of the second substrate.

11. The display device according to claim 10, wherein the oblique angle is between 15° and 60°.

12. The display device according to claim 9, wherein a height of the second substrate in a direction perpendicular to the array substrate is greater than that of the micro light emitting diodes.

13. The display device according to claim 9, wherein the quantum dot layers comprise red quantum dot layers and green quantum dot layers.

14. The display device according to claim 13, wherein the quantum dot layers are composed of a photocurable material comprising quantum dots.

15. The display device according to claim 9, wherein the second substrate is composed of gold, silver, or aluminum.

16. A method for fabricating a display device, comprising:
providing a first substrate having a plurality of metal electrodes;
providing a second substrate having a plurality of holes arranged in an array;
sanding and polishing the holes to form a plurality of reflective holes;
transferring a plurality of micro light emitting diodes to the first substrate;
bonding the second substrate to the first substrate to form a light emitting diode substrate, wherein the micro light emitting diodes are located in the reflective holes one by one; and
cutting the light emitting diode substrate to form a plurality of single micro light emitting diode devices.

17. The method for fabricating the display device according to claim 16, further comprising:
transferring the micro light emitting diode devices to an array substrate; and
filling quantum dot solutions in some of the reflective holes and curing them to form quantum dot layers covering the micro light emitting diodes.
